(19) United States
(12) Patent Application Publication
(10) Pub. No.: US 2023/0211991 A1
(43) Pub. Date: Jul. 6, 2023

(54) TRANSPORT DEVICE AND METHOD OF MOVING VACUUM SYSTEM COMPONENTS IN A CONFINED SPACE

(71) Applicant: Edwards Vacuum LLC, Sanborn, NY (US)

(72) Inventors: Willie Ashe, Hillsboro, OR (US); Lindsay Michelle Hardison, Hillsboro, OR (US); Brian Matthew Layng, Hillsboro, OR (US); Joshua Nathaniel Eric Mak, Hillsboro, OR (US); Gregory Ryan Le Mon, Hillsboro, OR (US)

(21) Appl. No.: 17/996,670

(22) PCT Filed: Apr. 30, 2021
(86) PCT No.: PCT/IB2021/053612

§ 371 Date: Oct. 20, 2022

(30) Foreign Application Priority Data
May 1, 2020 (GB) 2006455.6

(51) Int. Cl. B66F 9/12; B66F 9/075; B66F 9/20; B66F 9/06

(52) U.S. Cl. CPC B66F 9/12; B66F 9/20; B66F 9/063; B66F 9/07581

(57) ABSTRACT

A transport device includes rollable elements configured to both support and move the transport device on a surface; and a drive mechanism for driving the rollable elements. A load bearing mechanism is movable between a lowered position adjacent to the surface and at least one raised position, and is supported by a support frame having a front wall, two side walls and an open back. The load bearing mechanism is mounted such that the side walls and front wall of the support frame extend around the load bearing mechanism. An actuator is mounted on one of the walls of the support frame for controllably raising and lowering the load bearing mechanism and the rollable elements are mounted adjacent to the side walls of the support frame and support the two side walls at four locations, such that a center of gravity is between the four locations.

### CROSS-REFERENCE TO RELATED APPLICATION

This application is a Section 371 National Stage Application of International Application No. PCT/IB2021/053612 filed Apr. 30, 2021, and published as WO 2021/220233 A1 on Nov. 4, 2021, the content of which is hereby incorporated by reference in its entirety and which claims priority of British Application No. 2006455.6, filed May 1, 2020.

### FIELD

The field of the invention relates to transport devices, for transporting loads within confined spaces, such as vacuum system components within a sub fab, that is the area under a semiconductor fabrication plant, or other loads within a work area.

### BACKGROUND

The moving of vacuum pumps within a sub fab is a challenging process. Vacuum pumps and other components within a vacuum system can be heavy, several hundred or even over a 1,000 Kg and the space within a subfab is limited.

Conventionally, movement of pumps has been done manually. In practice, this means that service personnel need to bend over and put two hands on the pump and push it to the location needed. Pumps are generally mounted on wheels. This can be very straining to the back and legs. Furthermore, there are times where features on the floor cause the wheels to get stuck and stop the momentum of the pump. When this happens, the pump may tip over.

Another method is to use one or more carts to transport the pump. This has the drawback of requiring the pump to be lifted up on to the cart before it can be transported. Sometimes two or three different carts are required to complete the task. Human interaction is needed to push the cart and this carries with it an associated risk of injury. Furthermore, it may take many hours to get the pump to the tool, wasting both tool and technician time and adding an unnecessary risk of injury to personnel.

It would be desirable to provide a transport device able to efficiently transport loads within a confined space.

The discussion above is merely provided for general background information and is not intended to be used as an aid in determining the scope of the claimed subject matter. The claimed subject matter is not limited to implementations that solve any or all disadvantages noted in the background.

### SUMMARY

A first aspect provides a transport device for transporting loads in a confined space, said transport device comprising: rollable elements configured to both support and move said transport device on a surface; a drive mechanism for driving said rollable elements; a load bearing mechanism mounted to be movable between a lowered position adjacent to said surface and at least one raised position; a support frame configured to support said load bearing mechanism and comprising a front wall, two side walls and an open back, said load bearing mechanism being mounted such that said side walls and front wall of said support frame extend around said load bearing mechanism in at least one of said raised and lowered positions; at least one actuator mounted on one of said walls of said support frame for controllably raising and lowering said load bearing mechanism; wherein said rollable elements are mounted adjacent to said side walls of said support frame and support said two side walls at four locations, such that a centre of gravity of said transport device is between said four locations.

The transport of loads within a confined space is a challenging process. The manual movement of loads, which may be mounted on wheels, ties up personnel, can cause injuries and may not be efficient. The use of lifting devices such as forklift trucks which lift loads on forks or prongs extending out the front of the device require a significant counterweight to inhibit the device from tipping. This in turn makes the forklift truck difficult to manoeuvre in tight spaces. The present invention has addressed these problems by providing a transport device with drivable rollable elements which are mounted on either side of a C-shaped support frame. This C-shaped support frame has an open back through which a load can be pulled or pushed. The support frame supports a load bearing mechanism which can move between a lowered and raised position and can lift the load when it is within the support frame.

The configuration of the support frame is such that the centre of gravity of the transport device with or without a load, is between the rollable elements. This means that there is no need for a counterweight projecting from one side of the transport device. In effect a compact stable transport device that can lift and transport substantial loads within confined spaces is provided.

In some embodiments, the load bearing area within the support fame is over 40% and in some embodiments over 60% of the total cross sectional area in the horizontal plane of the transport device. In effect the C-shape configuration of the support frame with a load bearing mechanism mounted within it provides a transport device where the load bearing surface is a substantial proportion of the area of the whole device.

Although the load bearing mechanism may have a number of forms, it may for example comprise a hook device which is configured to extend to the open back face of the support frame and grasp the load and then pull it in and lift it, in some embodiments said load bearing mechanism comprises a base plate. In some embodiments, said base plate is mounted such that said side walls and front wall of said support frame extend beyond a perimeter of said base plate.

A base plate provides a support mechanism suitable for supporting any type of load that can fit onto to the base plate, and it is simple to load and unload loads from.

In some embodiments, the base plate comprises a sloped edge adjacent to the open back face of the support frame.

A sloped edge provides a ramp like surface allowing a load to be pushed or pulled onto the base plate in a relatively smooth fashion.

In some embodiments, the load bearing mechanism is configured to support a load of over 120 kg, in some embodiments over 230 kg and in other embodiments over 1000 kg.

In this regard, embodiments are particularly applicable to transporting components for vacuum systems such as vacuum pumps within the confined space of a sub fab for example. Such pumps may often be several hundreds of kilos heavy and need to be transported between locations where they are serviced and locations where they are installed. The area in a sub fab where these components are installed is at a premium and thus, the space between installation sites is often very tight. A transport device according to an embodiment that is configured to support heavy loads, that has a relatively small cross-sectional area that extends around the area supporting the load and which is both stable when supporting the load and able to lift the load provides a particularly effective solution for the transport of these devices.

Although, the rollable elements may comprise a number of things, for example they may be caterpillars, or omnidirectional wheels, in some embodiments they comprise four wheels. In other embodiments they may comprise more than four wheels.

In some embodiments, the four wheels are located towards either end of the two side walls providing a stable device that does not easily tip. In some embodiments, the locations that the rollable elements support the side walls at are within 30%, in some embodiments within 20% of the length of the side wall from an end of the side wall.

In some embodiments, each of said four wheels are independently drivable allowing for translational and rotational movement of said transport device.

Providing wheels that are independently drivable leads to a manoeuvrable transport able to access and travel through confined spaces.

In some embodiments, said transport device comprises a loading mechanism configured to pull a load through said open back of said support frame when said load bearing mechanism is in said lowered position.

Although, a load may be manually mounted into the transport device, preferably the transport device has its own loading mechanism which can pull a load through the open back of the support frame.

In some embodiments, said side walls each comprise horizontally extending guides configured to support and guide said loading mechanism from a position towards said front wall to a position towards said open back face of said support frame and an actuator configured to drive said loading mechanism along said guides.

One way of moving the loading mechanism to a loading position adjacent to the back open face of the support frame is to use guides, which may be in the form of rails extending horizontally along the side walls and which guide the loading mechanism from the front wall to the open back face. The mechanism can then attach to the load and as the loading mechanism moves back along the guides towards the front wall, the load is pulled into the support frame.

Although, the loading mechanism may comprise a number of things, it may for example be a latching mechanism such as a hook configured to latch to a receiving mechanism on the load or it may be configured to wrap around the load, in some embodiments the loading mechanism comprises a magnet for pulling the load through the open back of the support frame.

The advantage of a magnet is it does not require the load to have any corresponding device to which it attaches, it simply needs it to be formed of a material that is attracted to a magnet such as steel. Furthermore, such a loading mechanism does not need to access the side or back of the device and provided the device is made of a magnetic material it will provide an effective way of pulling the load onto the support frame. In this regard, the load may be mounted on wheels and/or the floor may be a smooth floor or have a smooth low friction coating such as Teflon on which the load can slide when pulled.

In some embodiments, said magnet comprises a permanent magnet such as a rare earth magnet.

It may be advantageous if the magnet is a permanent magnet which allows the loading mechanism to be failsafe and not to release the load if there is a power failure.

In some embodiments, said transport device comprises:
sensors configured to sense a volume around said transport device; and
control circuitry configured to control said drive mechanism, said control circuitry being configured to receive signals from said sensors and to control said drive mechanism in response to said signals to inhibit said transport device from colliding with objects sensed by said sensors.

It may be advantageous if the transport device comprises sensors that are able to sense around the transport device and which when associated with control circuitry that controls the drive mechanism are able to inhibit the transport device from colliding with objects. This may be an effective safety mechanism and may also be particularly advantageous where the transport device is carrying heavy and valuable loads within a confined space.

In some embodiments the transport device is a semi-autonomous device which can be controlled using a remote controller, while in other embodiments the transport device is an autonomous transport device able to be programmed to automatically collect, move and unload loads between different locations as required.

In some embodiments, said transport device comprises at least three guides, one mounted in each of said planes comprising said side walls and front wall, and each extending vertically and being configured to guide said load bearing mechanism between said raised and lowered positions.

In order to stably be able to move the load bearing mechanism between the raised and lowered positions, in some cases the transport device may be fitted with guides that can guide the loading mechanism as it moves between the positions and thus, hold it horizontally and inhibit it from tipping thereby allowing the load to be safely raised or lowered.

In some embodiments, there are four guides and these four guides may be located towards the corners of the base plate.

In some embodiments, said at least one actuator is configured to controllable move said load bearing mechanism between a lowered and a plurality of different raised positions.

The actuator may be able to control the load bearing mechanism to move between several different raised positions and this may be advantageous where a load is being moved to a location where it is to be mounted perhaps in a support frame above the ground.

In some embodiments, said transport device comprises two actuators, one mounted on each side of the wall of said transport device.

Although, there may be only one actuator and in such a case it may be mounted on the front wall and provide the driving mechanism to move the load bearing mechanism while the guides provide the supports that help to hold the load bearing mechanism horizontal, in other embodiments there may be an actuator on each side wall.

In some embodiments, said transport device further comprises a frame comprising corner members extending vertically upwards from said support frame of said transport device, wherein said transport device comprises four of said guides, said four of said guides being attached to said corner members of said frame and being configured to guide said load bearing mechanism from said lowered position to said plurality of raised positions.

In some cases the transport device may be used to transport loads not only between locations at floor level, but also to locations where the loads may be mounted at different heights. In such a case, it may be advantageous for the transport device to have a frame such that the load bearing mechanism can be moved between different raised positions, some of which reach to a relatively high height. In this case, the guides may be attached to the four corner members of the frame and may serve to hold the load bearing mechanism at each corner and maintain it and thus, the base of the load horizontal.

In some embodiments, said base plate comprises barrier members extending vertically upwards from a front and sides of said base plate.

Where the load bearing mechanism is a base plate and where the transport device has a frame allowing it to lift the base plate to a substantial height, it may be advantageous for the base plate to have barrier members extending vertically upwards from the front and sides of the base plate to hold the load in place and inhibit it from falling and exiting the transport device except out of the open back face as required.

A second aspect provides a method of moving vacuum system components within a sub fab, said method comprising:
moving said transport device adjacent to a vacuum system component;
lowering a load bearing mechanism of said transport device;
using the loading mechanism of said transport device to pull said vacuum system component though an open back face of a support frame of said transport device such that it is supported by said load bearing mechanism;
raising said load bearing mechanism;
driving said transport device to a different location within said sub fab;
performing one of lowering or raising said load bearing mechanism; and
unloading said vacuum system component.

The transport device of the first aspect is particularly applicable to moving vacuum system components within a sub-fab. These components are valuable, may be bulky and may weigh a considerable amount. Furthermore, they need to be moved within a confined space and as interrupting the operation of a sub-fab is extremely costly, it is advantageous if the movement of the components can be done quickly and efficiently. Providing transport devices which are compact, can be driven at least semi-autonomously and in some cases autonomously, which can carry significant loads and which are adept at moving in tight circles and in tight spaces makes them particularly effective for this purpose. Furthermore, the ability to raise the load to one of a plurality of different heights may be effective where vacuum system components are mounted within stacked frames.

Further particular and preferred aspects are set out in the accompanying independent and dependent claims. Features of the dependent claims may be combined with features of the independent claims as appropriate, and in combinations other than those explicitly set out in the claims.

Where an apparatus feature is described as being operable to provide a function, it will be appreciated that this includes an apparatus feature which provides that function or which is adapted or configured to provide that function.

The summary is provided to introduce a selection of concepts in a simplified form that are further described in the detailed description. This summary is not intended to identify key features or essential features of the claimed subject matter, nor is it intended to be used as an aid in determining the scope of the claimed subject matter.

### BRIEF DESCRIPTION OF THE DRAWINGS

Embodiments of the present invention will now be described further, with reference to the accompanying drawings, in which:

FIG. 1 shows a transport device and load prior to loading according to an embodiment;

FIG. 2 shows a transport device with the load mounted on the base plate;

FIG. 3 shows a transport device with the base plate raised and the load in position;

FIG. 4 shows a plan view of a transport device with load in place;

FIG. 5 shows a transport device according to an embodiment;

FIG. 6 shows a plan view of a transport device without a load in place;

FIG. 7 shows a plan view of a transport device with the loading mechanism in a position about to load a load;

FIG. 8 shows a side view of a transport device with a load mechanism attached to a load;

FIG. 9 shows a transport device loading a load;

FIG. 10 shows a transport device with a load in place;

FIG. 11 shows a multi-level transport device according to an embodiment

FIG. 12 schematically shows drive and control circuitry for controlling operation of the transport mechanism; and

FIG. 13 schematically shows a flow diagram illustrating steps in a method according to an embodiment.

### DETAILED DESCRIPTION

Before discussing the embodiments in any more detail, first an overview will be provided.

Moving heavy objects within a confined space, such as vacuum pumps within a sub fab is a very challenging task and can cause injury to personnel due to the weight of the pump (may typically be 1200 Kg) and their size. Pumps often need to be pushed to the location where they will be installed. The floor can have various topographical variations and these can damage the pump wheels, or the wheels can get caught and stop the pump from moving. If a cart is used to move the pump it then becomes challenging to fit in the corridors/paths that need to be followed to access the installation location/Frame. Furthermore, other devices will need to be used to lift the pump on the cart in the first place.

Embodiments provide an autonomous ground vehicle (AGV) with a C-shaped frame that allows the pump to be pulled into the centre of the frame onto a plate. This in turn allows the AGV to lift the pump and then ultimately move it via motorized wheels and controls. This removes the need for human force to be used. In some embodiments the transport device can be moved fully autonomously with the help of sensors configured to sense objects and inhibit any collisions with machinery, humans and/or debris in the paths. In other embodiments the transport device can be moved in a semi autonomous mode with a remote controller. Collisions are still inhibited with the use of the sensors.

FIG. 1 shows a transport device 10 according to an embodiment that is moving into position to transport a load 60, which in this embodiment comprises a vacuum pump. Transport device 10 moves adjacent to load 60 with the open back facing the load. The load bearing mechanism which in this embodiment comprises base plate 50 is lowered adjacent to the floor ready to receive load 60. Base plate 50 has a sloped surface facing pump 60 such that pump 60 rolls up the slope surface when grasped by loading mechanism, in this embodiment magnet 72.

Transport device 10 comprises four wheels 12 which are located substantially towards the corners of support frame 20 of the transport device. This provides a stable transport device where the centre of gravity lies between the four wheels 12 and substantially towards the centre of the transport device in the horizontal plane.

Load bearing mechanism is in this embodiment base plate 50 and this can be raised and lowered using actuators 40 attached to either side walls of support frame 20. Movement of base plate 50 is guided by four guides 30 two of each being arranged on either side wall. Thus, actuator 40 provides the raising and lowering force while the guides restrain movement to the vertical plane inhibiting any tilting of base plate 50.

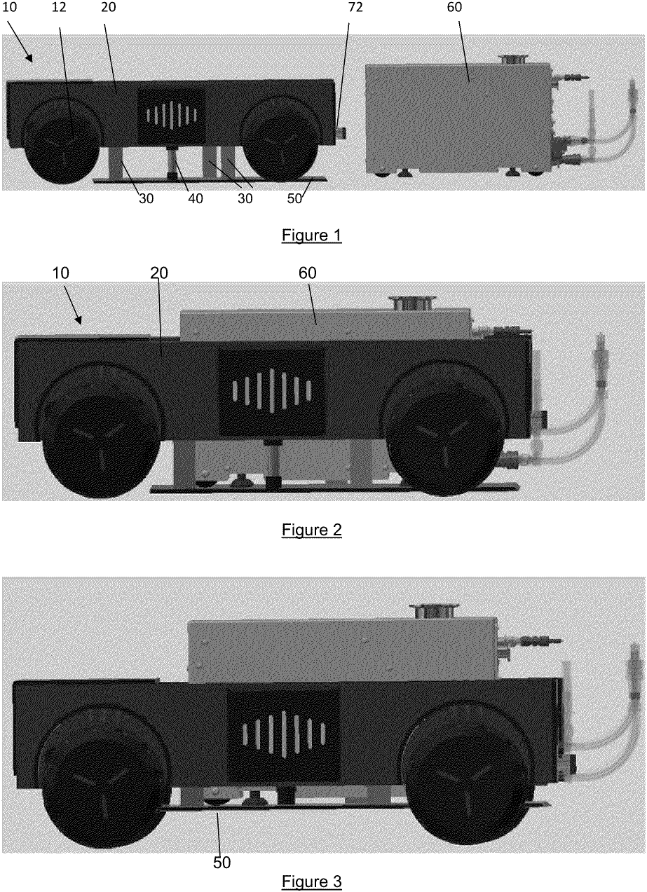

FIG. 2 shows the load 60 mounted on the base plate within transport device 10.

Once the load 60 is within the support frame 20 actuator 40 is actuated and raises base plate 50 to a raised position with any horizontal movement being restrained by guides 30 (see FIG. 3). At this point transport device 10 is ready to move to a destination location.

Each of wheels 12 are individually drivable making for a device which is very manoeuvrable and can access and move between confined spaces.

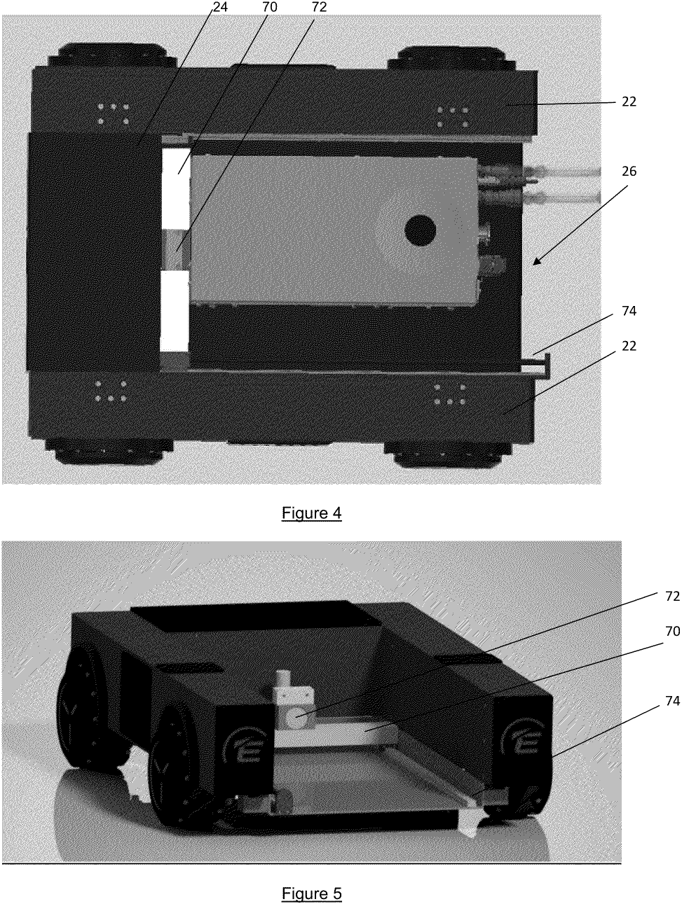

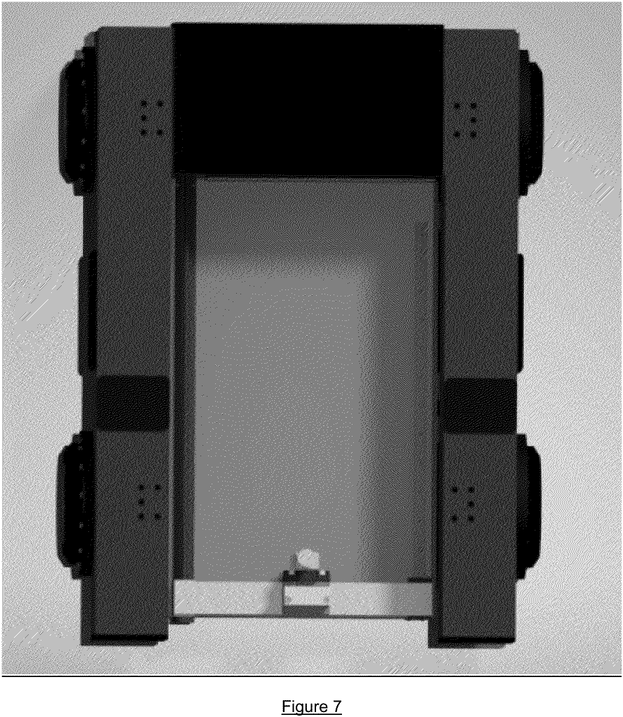

FIG. 4 shows an overhead plan view of transport device 10 and in particular the support frame 20 and loading mechanism 70. Support frame 20 has two side walls 22 and a front wall 24. There is an open back 26 through which the load 60 can be loaded and unloaded. This figure shows in more detail loading mechanism 70 which in this embodiment comprises a horizontal bar and a rare earth magnet 72. Loading mechanism 70 is driven along guide rails 74 which extend horizontally along side walls 22. The loading mechanism can move between a loaded position shown in FIG. 4 where it is adjacent to front wall 24 and a loading position which is shown in FIG. 7.

FIG. 5 shows an alternative view of transport device 5 without the load in it and with the loading mechanism in a rest position. There is a motor arranged adjacent to the magnet 72 which is configured to move the loading mechanism along the rails to the open back of the transport device, when a load is to be loaded.

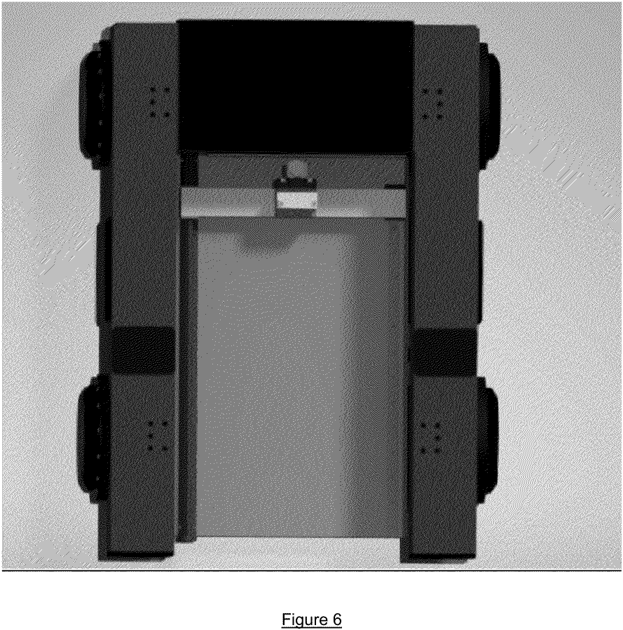

FIG. 6 shows a plan view of the loading mechanism in the rest position which is the position adopted during movement of the transport device, and FIG. 7 shows the same view with the loading device having moved along the rails such that it is adjacent to the open back of the transport device ready to engage with a load and pull it into the device.

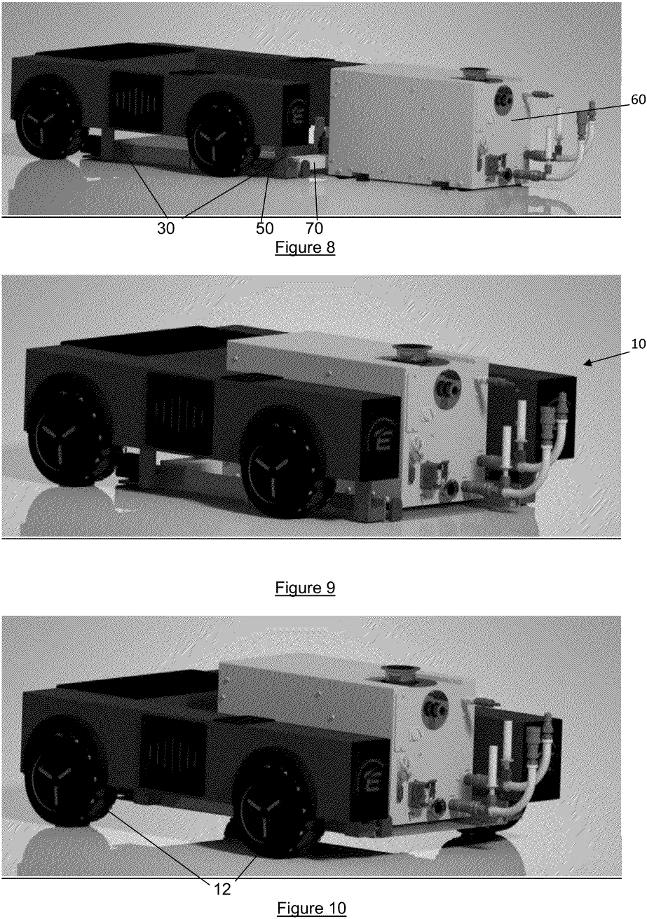

FIG. 8 shows a pump 60 being held by the loading mechanism prior to be pulled into the transport device in FIG. 9. In this embodiment, guides 30 for guiding the base plate during vertical movement are towards the corners of the base plate 50, which makes for a more robust and stable support for the base plate. Transport device 10 has been moved into the position shown in FIG. 8 under control of control circuitry such that the open back of the transport device is adjacent to load 60. Loading mechanism 70 with magnet (not shown) has been moved towards the open back of the transport device and contacts load. Loading mechanism 70 is then moved horizontally along the side walls of the support frame 20 towards the front wall pulling load 60 onto base plates 50 and into the support frame 20.

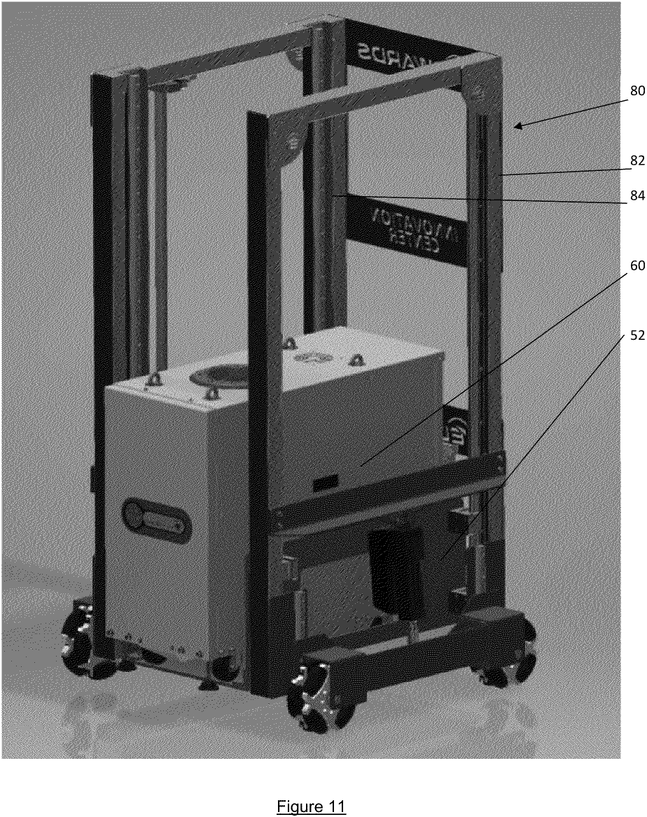

Once within the transport device the base plate 50 is lifted as is shown in FIG. 10, whereupon the transport device is ready to move by driving the independently driven wheels 12.

FIG. 11 shows an alternative embodiment comprising a frame 80 having four corner support members 82 each having guides 84 running along them. In this embodiment base plate comprises two side walls 52 and a back wall which act as barriers to impede load 60 from toppling from base plate. As can be seen, in this embodiment the frame 80 allows load 60 to be moved to a substantial height and in some embodiments it is able to raise it to one of several different heights and thus, it can be unloaded and loaded into a stacked position in different integrated vacuum systems. This allows a single device to both load and unload a substantial load to one of several different locations and one of several different heights.

In all of these embodiments, the wheels 12 are independently driven by a drive mechanism which is not shown. Furthermore, there is control circuitry associated with this drive mechanism and sensors which sense the area around the transport device 10 and which in conjunction with the control circuitry which controls the driving of the wheels 12 inhibit the transport device 10 from colliding with objects.

In some embodiments, the control circuitry and drive mechanism are such that the movement of transport device 10 is entirely autonomous, while in other embodiments there is a receiver for receiving signals from a remote control and the movement of the transport device can be controlled by the remote control and is thus, semi-autonomous.

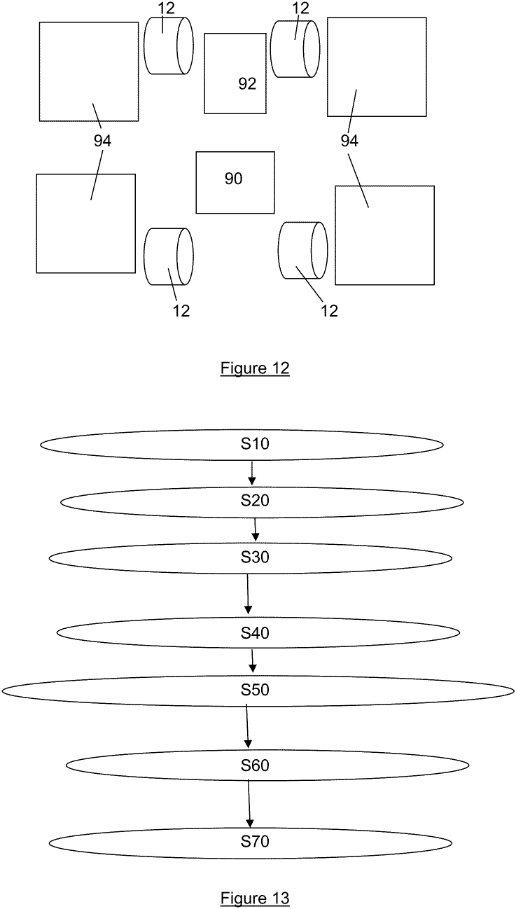

FIG. 12 schematically shows the control circuitry for controlling the driving of the transport mechanism 10. There is drive circuitry 90 for independently controlling the driving wheels 12. There is control circuitry 92 that either receives instructions from a remote device indicating the transport requirements or is programmed with particular transport instructions. The control circuitry 92 receives signals from sensors 94 sensing the area around the transport device and sends control signals based on both the transport instructions and the signals from the sensors to drive circuitry 90 which in turn controls the movement of the individual wheels 12

FIG. 13 schematically shows steps in a method of moving a pump using a transport device according to an embodiment. Initially at step S10, the transport device is moved adjacent to the pump, with the open back facing the pump under control of the control circuitry controlling the driving of the wheels. When in location at step S20 the transport device lowers the base plate and at step S30 the loading mechanism is moved to grasp the pump and pull it onto the base plate. Once in position, the load will continue to be held by the loading mechanism and the base plate will be raised at step S40. The transport device can then move to the destination location under control of control circuitry at step S50 and at this new location the base plate will be lowered in step S60 and the pump unloading by the loading mechanism moving in the reverse direction to push the pump away from the front wall and out of the open back at step S70.

In summary embodiments provide a transport device configured for:

Lifting a pump from the ground into the C frame of the device, raising it off the ground and securely holding it in the C frame.

In embodiments a work flow manager will task the transport device to do the necessary work planning and work load priority using control circuitry 92.

Similarly for the return for repair the transport device will return it to the store’s location for service under control of the control circuitry 92.

Although illustrative embodiments of the invention have been disclosed in detail herein, with reference to the accompanying drawings, it is understood that the invention is not limited to the precise embodiment and that various changes and modifications can be effected therein by one skilled in the art without departing from the scope of the invention as defined by the appended claims and their equivalents.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are described as example forms of implementing the claims.

1. A method of moving vacuum system components within a sub fab, said method comprising:
moving said transport device adjacent to a vacuum system component;
lowering a load bearing mechanism of said transport device;
using the loading mechanism of said transport device to pull said vacuum system component though an open back face of a support frame of said transport device such that it is supported by said load bearing mechanism;
raising said load bearing mechanism;
driving said transport device to a different location within said sub fab;
performing one of lowering or raising said load bearing mechanism; and
unloading said vacuum system component.

2. A transport device for transporting loads in a confined space, said transport device comprising:
rollable elements configured to both support and move said transport device on a surface;
a drive mechanism for driving said rollable elements;
a load bearing mechanism mounted to be movable between a lowered position adjacent to said surface and at least one raised position;
a support frame configured to support said load bearing mechanism and comprising a front wall, two side walls and an open back, said load bearing mechanism being mounted such that said side walls and front wall of said support frame extend around said load bearing mechanism in at least one of said raised and lowered positions;
at least one actuator mounted on one of said walls of said support frame for controllably raising and lowering said load bearing mechanism; wherein
said rollable elements are mounted adjacent to said side walls of said support frame and support said two side walls at four locations, such that a centre of gravity of said transport device is between said four locations.

3. The transport device according to claim 2, wherein said load bearing mechanism comprises a base plate, said base plate being mounted such that said side walls and front wall of said support frame extend beyond a perimeter of said base plate.

4. The transport device according to claim 2, wherein said rollable elements comprise four wheels.

5. The transport device according to claim 4, wherein each of said four wheels are independently drivable allowing for translational and rotational movement of said transport device.

6. The transport device according to claim 2, wherein said transport device comprises a loading mechanism configured to pull a load through said open back of said support frame when said load bearing mechanism is in said lowered position.

7. The transport device according to claim 6, wherein said side walls each comprise horizontally extending guides configured to support and guide said loading mechanism from a position towards said front wall to a position towards said back face of said support frame and an actuator configured to drive said loading mechanism along said guides.

8. The transport device according to claim 6, wherein said loading mechanism comprises a magnet for pulling said load through said open back of said support frame.

9. The transport device according to claim 8, wherein said magnet comprises a permanent magnet such as a rare earth magnet.

10. The transport device according to claim 2, wherein said transport device comprises:
sensors configured to sense a volume around said transport device; and
control circuitry configured to control said drive mechanism, said control circuitry being configured to receive signals from said sensors and to control said drive mechanism in response to said signals to inhibit said transport device from colliding with objects sensed by said sensors.

11. The transport device according to claim 2, wherein said transport device comprises an autonomous transport device.

12. The transport device according to any of claim 2, wherein said transport device comprises at least three guides, one mounted in each of said planes comprising said side walls and front wall, and each extending vertically and being configured to guide said load bearing mechanism between said raised and lowered positions.

13. The transport device according to claim 2, wherein said at least one actuator is configured to controllable move said load bearing mechanism between a lowered and a plurality of different raised positions.

14. The transport device according to claim 12, said transport device further comprising a frame comprising corner members extending vertically upwards from said support frame of said transport device, wherein said transport device comprises four of said guides, said four of said guides being attached to or forming part of said corner members of said frame and being configured to guide said load bearing mechanism from said lowered position to said plurality of raised positions.

15. The transport device according to claim 14, wherein said load bearing mechanism comprises a base plate, said base plate being mounted such that said side walls and front wall of said support frame extend beyond a perimeter of said base plate and wherein said base plate comprises barrier members extending vertically upwards from a front and sides of said base plate.
